(19) United States
(12) Patent Application Publication
(10) Pub. No.: US 2007/0042553 A1
(43) Pub. Date: Feb. 22, 2007

(54) Fabrication method for semiconductor memory components

(76) Inventors: Karl-Heinz Kuesters, Boxdorf (DE); Stephan Riedel, Dresden (DE); Josef Willer, Riemerling (DE)

Correspondence Address: SLATER & MATSIL LLP, 17950 PRESTON ROAD, SUITE 1000, DALLAS, TX, 75252, US

(21) Appl. No.: 11/506,159

(22) Filed: Aug. 17, 2006

(30) Foreign Application Priority Data
Aug. 17, 2005 (DE) 10 2005 038 939.2

(51) Int. Cl. H01L 21/8236

(52) U.S. Cl. 438/278

(57) ABSTRACT

A storage layer sequence (20) and gate electrodes (34) are arranged on a substrate (10). The gate electrodes (34) may be fabricated in a gate electrode layer (22) made of electrically conductively doped polysilicon. Apart from an optional barrier layer (45), the word lines are solely formed from a material having a low resistivity, preferably from a metal layer (46). Word line spacers (52) are arranged on sidewalls for the purpose of electrical insulation and as a barrier against outdiffusion of metal atoms.

This application claims priority to German Patent Application 10 2005 038 939.2, which was filed Aug. 17, 2005 and is incorporated herein by reference.

### TECHNICAL FIELD

The present invention relates to semiconductor memory components, and in one example to charge trapping semiconductor components.

### BACKGROUND

German Patent Application Serial No. 101 10 150 A1 and corresponding U.S. Pat. No. 6,686,242, each of which is incorporated herein by reference, describe a method for fabricating metallic bit lines for memory cell arrays, in which doped wells are fabricated at a main side of a semiconductor substrate and a storage layer sequence made of dielectric materials suitable for charge trapping is applied over the whole area. A gate region layer made of polysilicon that is provided for the gate electrodes is applied over the whole area and patterned in strip-type fashion along the bit lines to be fabricated. Buried bit lines are fabricated between the strips by implantation of dopant into the semiconductor material of the substrate. Metallic bit lines are fabricated directly on the doped regions by deposition of a suitable metal layer. The gate region layer is uncovered at the top side, with the result that it can be contact-connected to a first word line layer provided for the word lines, the word line layer likewise being polysilicon. This is followed by at least one metallic layer, for example a layer made of WSi, or a layer sequence made of tungsten nitride and tungsten. The layers provided for the word lines are then patterned according to the word lines to form word line stacks. In this case, the strip-type portions of the gate region layer are also separated into individual gate electrodes made of polysilicon.

However, further miniaturization of the memory components necessitates reducing the cross sections of the interconnects. As a result, the electrical resistance of the interconnects increases, but the resistance is intended to be as low as possible in order as far as possible to avoid a voltage drop along the line and to enable a sufficiently short switching time. On the other hand, the number of layers provided for the word lines should not be too high; the thickness of the layers must be kept as small as possible in order to keep the aspect ratio between the height of the word line stacks and the width thereof within appropriate limits. A multilayer word line layer including a polysilicon layer is, therefore, suitable only to a limited extent for further minimization of the memory components.

### SUMMARY OF THE INVENTION

In one aspect, the present invention provides a fabrication method for a semiconductor memory component that makes it possible to reduce the electrical resistance of the word lines and at the same to obtain a smallest possible height of the word line stacks.

This aspect is achieved by means of the fabrication method wherein a storage layer sequence is formed over a semiconductor body. Gate electrodes are formed adjacent the storage layer sequence, the gate electrodes including strip-type structures made of electrically conductive material. Source/drain regions are formed by an implantation of dopant into the semiconductor body between the gate electrodes. A dielectric filling is formed between the gate electrode layer and word lines are formed from at least one metal layer that makes electrical contact with the gate electrodes. A dielectric material is provided adjacent free sidewalls that encompass an upper region of the gate electrodes, the dielectric material forming word line spacers. A further dielectric filling is formed into regions between mutually adjacent word lines and between mutually adjacent gate electrodes.

In the case of the semiconductor memory component, bit lines and word lines running transversely with respect thereto are arranged at a main side of a semiconductor substrate. The word lines connect the gate electrodes made of electrically conductive material, preferably made of conductively doped polysilicon, of the individual memory cells to one another in rows. The memory cells each have source/drain regions on both sides of the gate electrodes. At every location the word lines have an ohmic resistivity that is lower than the ohmic resistivity of highly doped silicon or highly doped germanium. The value of the ohmic resistivity of highly doped polysilicon of the order of magnitude of around 1000 μΩcm is typical of these comparative resistivities.

The word lines are preferably formed completely from metal having less than 5 percent of nonmetallic atoms or impurities. A material of this type is defined as pure metal in the context of this invention. Accordingly, the material of the word lines only has at most a proportion of impurities with a magnitude such that the electrical bulk resistance of the word lines remains sufficiently low and lies below the values of highly doped silicon or highly doped germanium. A resistivity of less than 15 μΩcm, in particular, can be achieved in this way. The word lines are preferably pure tungsten or pure molybdenum if the method provides further steps at a high temperature of 1000° C. or more, which the word lines must withstand. The metals can be applied not only by CVD (chemical vapor deposition) but also by sputtering. Preferred refinements provide for surrounding the word lines with material that has properties of a barrier in order to prevent the outdiffusion of metal atoms from the word lines into the surrounding material. Nitride layers, in particular, are suitable for this purpose.

In the case of the fabrication method, a metal layer that is practically pure in the above sense, or a layer sequence made of pure metals, and is provided for the word lines may firstly be applied over the whole area on the top side and on parallel strips of a gate electrode layer. The metal forms a low-value contact resistance with respect to the electrically conductive material of the gate electrodes; if appropriate, a thin adhesion layer may additionally be arranged between the gate electrode layer and the word lines. The word line stacks are then etched at least into a certain depth into the strip-type portions of the gate electrode layer and subsequently provided with electrically insulating spacers at the sides, which spacers bring about, in particular, an encapsulation of the word lines that protects the material of the word lines in optionally required subsequent steps performed at high temperature. Such a material having a good barrier effect against outdiffusion of the metal atoms from the word line is preferably chosen for this purpose. A nitride of the semiconductor material, in particular silicon nitride, is especially suitable for this purpose. The word line stacks are then also completely patterned, if appropriate, so that the gate electrodes of the individual memory cells are separated from one another.

Instead of this, a hard mask may firstly be applied and patterned in the form of the word line stacks to be fabricated. A dielectric material with respect to which the material of the hard mask can be etched selectively is introduced between the portions of the hard mask that are patterned in strip-type fashion. When the hard mask has been removed, the openings fabricated in this way can be filled with the material of the word lines. By this means, too, word lines are formed that are composed completely of a material having a low ohmic resistance, preferably of pure metal.

### BRIEF DESCRIPTION OF THE DRAWINGS

Examples of the semiconductor memory component and associated fabrication methods are described in more detail below with reference to the accompanying figures.

FIG. 1 shows a plan view of a detail from a memory component with the arrangement of the word lines and bit lines;

FIG. 2 shows a cross section through an intermediate product of a memory component after the fabrication of a storage layer sequence and a gate electrode layer;

FIG. 3 shows the cross section in accordance with FIG. 2 after strip-type patterning of the gate electrode layer;

FIG. 4 shows the cross section in accordance with FIG. 3 after the implantation of buried bit lines and a lateral insulation of the gate electrodes;

FIG. 5 shows the cross section in accordance with FIG. 4 after the application of a metal layer provided for word lines;

FIG. 6A shows a cross section through the intermediate product illustrated in FIG. 5 at the correspondingly marked location;

FIG. 6B shows a cross section through the intermediate product illustrated in FIG. 5 at the further marked location;

FIG. 7A shows the cross section in accordance with FIG. 5 for an alternative embodiment of the fabrication method;

FIG. 7B shows the cross section in accordance with FIG. 7A for a modification of the fabrication method;

FIG. 8A shows the cross section in accordance with FIG. 6A for the intermediate product in accordance with FIG. 7A;

FIG. 8B shows the cross section in accordance with FIG. 6B for the intermediate product in accordance with FIG. 7A;

FIG. 9A shows the cross section in accordance with FIG. 8A after the fabrication of the word lines; and

FIG. 9B shows the cross section in accordance with FIG. 8B after the fabrication of the word lines.

The following list of reference symbols can be used in conjunction with the figures:
2 Word line 32 Implantation region
4 Bit line 34 Gate electrode
6 Channel region 36 Spacer
8 pn junction 38 Bit line
10 Substrate 42 Dielectric filling
12 Doped well 43 Further dielectric filling
14 Lower boundary layer 45 Barrier layer
16 Storage layer 46 Metal layer
18 Upper boundary layer 47 First metal layer
20 Storage layer sequence 48 Second metal layer
22 Gate electrode layer 50 Hard mask
24 Hard mask layer 52 Word line spacer
26 Further hard mask layer 54 Anti-punch implantation region
30 Opening

### DETAILED DESCRIPTION OF ILLUSTRATIVE EMBODIMENTS

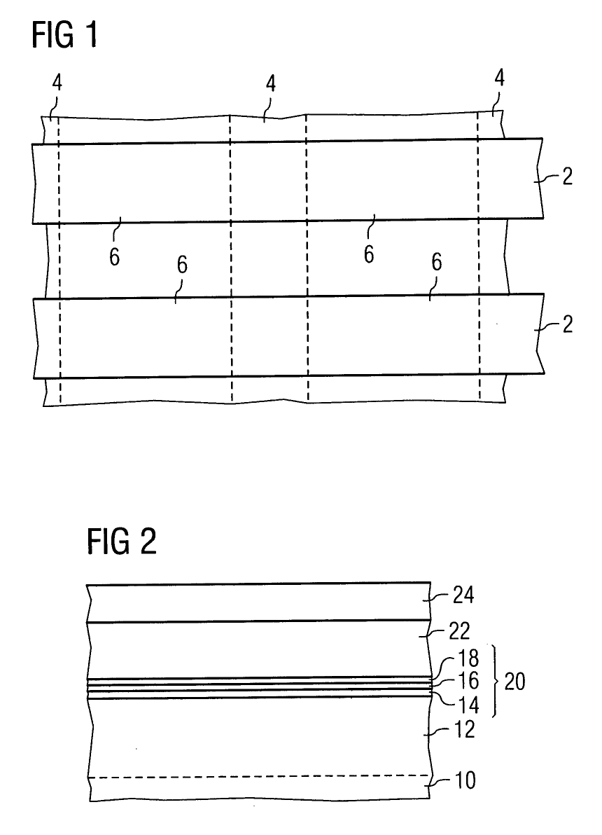

FIG. 1 shows a plan view of a detail from a semiconductor memory component with the arrangement of the word lines 2 and bit lines 4. Beneath the word lines 2, the channel regions 6 of the individual memory transistors are situated in the regions between the bit lines 4. The bit lines 4 are formed here as buried bit lines in the semiconductor material and comprise the source/drain regions of the memory cells on both sides of the channel regions 6.

FIG. 2 shows a cross section through an intermediate product of the semiconductor memory component, in which a storage layer sequence 20 is applied on a substrate 10, at the main side of which is formed a doped well 12 having the basic doping of the channel regions. The storage layer sequence 20 is provided here for the fabrication of charge trapping memory cells and comprises a lower boundary layer 14, a storage layer 16 and an upper boundary layer 18 made of dielectric materials. The storage layer 16 is a dielectric suitable for charge trapping, such as silicon nitride. The boundary layers 14, 18 may be an oxide of the semiconductor material, e.g., silicon dioxide. A gate electrode layer 22 is applied on the storage layer sequence 20 applied over the whole area, and the gate electrode layer is patterned in strip-type fashion using a hard mask layer 24. The gate electrode layer 22 is preferably polysilicon that is electrically conductively doped. The hard mask layer 24 may be silicon nitride, for example, which is patterned by means of photolithography using a photoresist layer (not shown) to form a mask.

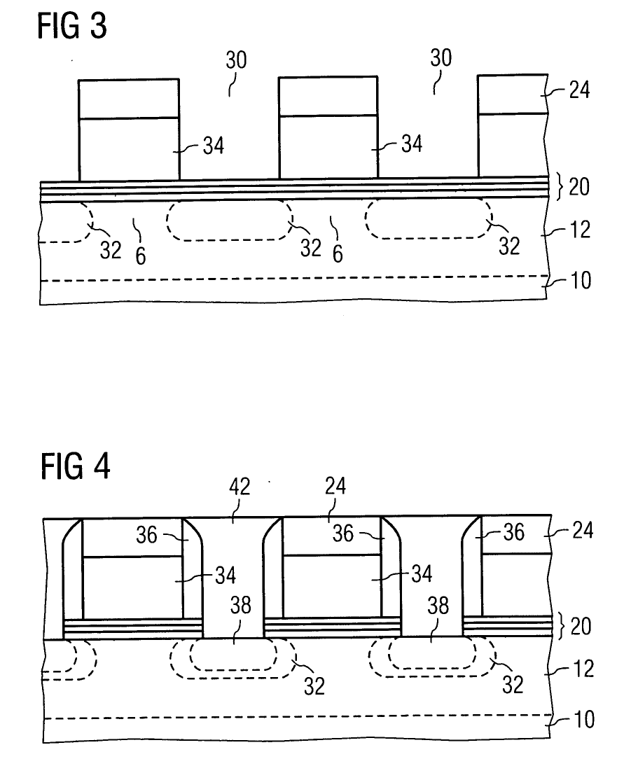

FIG. 3 shows the intermediate product thus obtained in a cross section transversely with respect to the strip-type remaining portions of the gate electrode layer, which comprise the gate electrodes 34 provided for the individual transistor structures of the memory cells. The remaining portions of the gate electrode layer are strips that are arranged parallel to one another and are separated from one another by the openings 30. The cross section of the gate electrodes 34 and of the hard mask layer 24 as illustrated in FIG. 3 continues perpendicular to the plane of the drawing in front of and behind the plane of the drawing.

The openings 30 between the gate electrodes 34 extend at least down to the upper boundary layer 18 of the storage layer sequence 20. An implantation region 32 may in each case be fabricated between the channel regions 6, the basic doping of the doped well 12 being increased in the implantation region by means of an implantation of dopant in order to obtain harder pn junctions with respect to the buried bit lines that are to be implanted later, so that the difference between the n-type conductivity and the p-type conductivity is greater there. However, the implantation regions 32 provided for the hard pn junctions may also be omitted.

FIG. 4 shows a further intermediate product in the cross section in accordance with FIG. 3. The sidewalls of the strips comprising gate electrode layer and hard mask layer are preferably, but not necessarily, covered with spacers 36 that are preferably fabricated as a silicon nitride layer in a known manner. For example, the spacers can be formed by conformal deposition of a whole-area layer and anisotropic etching-back. The etching of the spacers preferably also involves removing a portion of the storage layer sequence 20 that is possibly still present in the regions between the spacers. However, it is also possible for part of the storage layer sequence, in particular the lower boundary layer 14, to remain as a screen layer for the subsequent implantation.

The buried bit lines 38, which also comprise the source/drain regions of the individual memory cells, are formed by means of an implantation of dopant. The openings 30, possibly between the spacers 36, are filled with a dielectric filling 42. However, the spacers 36 may, if present, also be removed first before the introduction of the dielectric filling 42. The hard mask 24 is removed prior to the application of the word line layer provided for the word lines. In this case, the dielectric filling 42 may be insipiently etched and, in particular, be removed to an extent such that the top side of the intermediate product obtained is essentially planar.

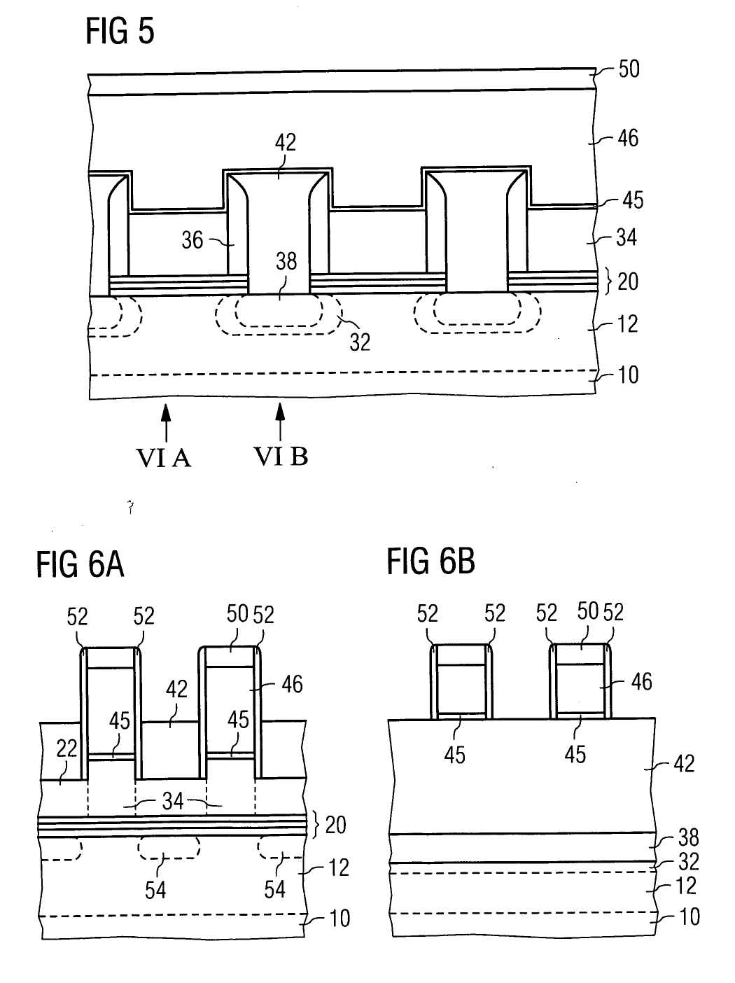

FIG. 5 shows the cross section in accordance with FIG. 4 for an exemplary embodiment with a non-planarized top side after the application of a metal layer 46, which is provided for the word lines and, which may be, for example, tungsten or molybdenum or some other (refractory) metal that is stable with respect to high temperatures. A thin barrier layer 45 is preferably additionally applied prior to the application of the metal layer 46. The barrier layer can also serve as an adhesion layer and improve the adhesion of the metal layer 46 and thus, in particular, the electrical contact between the metal layer 46 and the gate electrodes 34. As already specified, the metal layer 46 is a material that has at most 5% of impurities and a lower ohmic resistance than highly doped germanium or highly doped silicon. The hard mask 50 on the top side serves for patterning the metal layer 46 to form word lines. The positions of the cross sections transversely with respect to the word lines that are represented in FIGS. 6A and 6B are marked in FIG. 5.

FIG. 6A shows a cross section through the intermediate product in accordance with FIG. 5 in the region of the gate electrodes 34. It can be discerned in FIG. 6A that the hard mask 50 is patterned in strip-type fashion, so that it is thereby possible to etch strip-type word line stacks essentially comprising the metal layer 46. The patterning of the word line stacks is effected right into the gate electrode layer 22, but not necessarily completely down to the storage layer sequence 20. The word line spacers 52 depicted are then fabricated at the sidewalls of the word line stacks formed thus far, which may again be done by conformal deposition of a whole-area layer and anisotropic etching-back. The gate electrodes 34 present in the strips of the gate electrode layer 22 that have remained, if appropriate, are identified by the dashed contours. The material of the gate electrode layer 22 that is still present, if appropriate, outside the dashed contours is subsequently etched away down to the storage layer sequence 20. In the viewing direction illustrated in FIG. 6A, the sidewall of the dielectric filling 42 that is present behind the plane of the cross section illustrated can be discerned between the etched word line stacks. Anti-punch implantation regions 54 may be formed by introducing dopant and serve to better insulate the buried bit lines and the channel regions of successive cells from one another.

FIG. 6B shows a cross section running in coplanar fashion with respect to the cross section of FIG. 6A between two gate electrodes 34. Here the metal layer 46 is situated only on the top side of the dielectric filling 42. The bit lines 38 present within the implantation region 32 can be discerned in this cross section. The remaining parts correspond to the structures indicated in FIG. 6A and are provided with the same reference symbols.

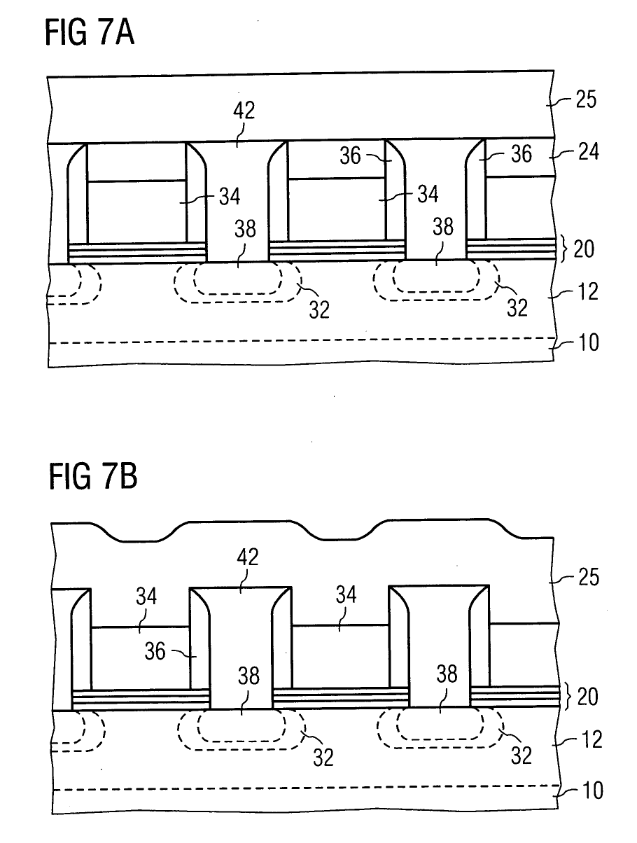

An exemplary embodiment of the semiconductor memory component with word lines formed completely from pure metal can also be fabricated by an alternative fabrication method, which is described below with reference to the further figures. FIG. 7A shows the cross section in accordance with FIG. 4 after the application of a further hard mask layer 25. The corresponding cross section in FIG. 7B illustrates that instead, prior to the application of the further hard mask layer 25, it is possible firstly to remove the hard mask layer 24 on the residual strips of the gate electrode layer. The further hard mask layer 25 is then patterned photolithographically in the dimensions of the word lines to be fabricated.

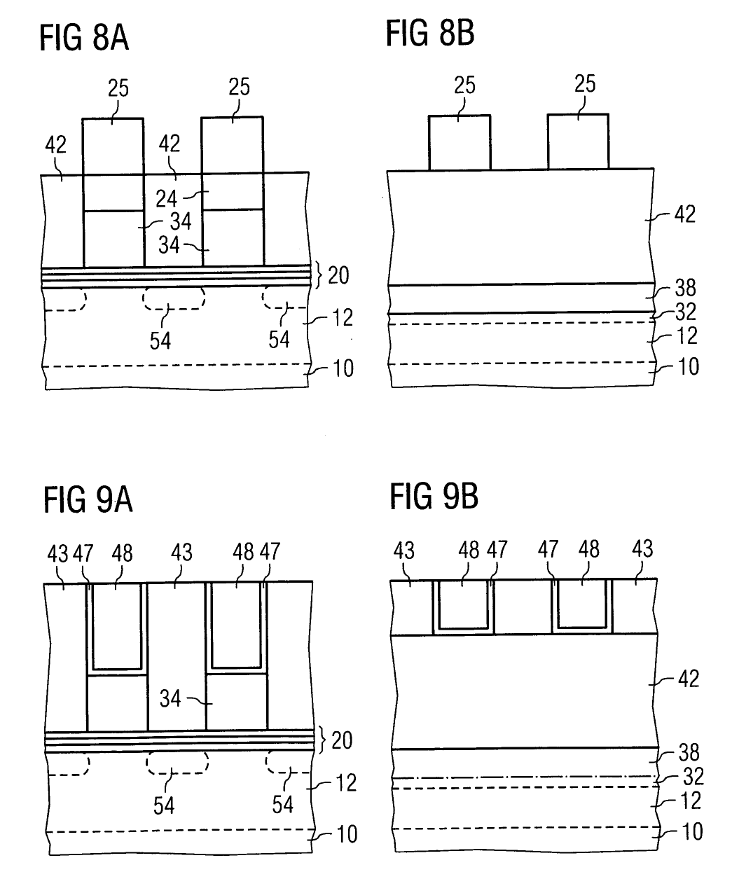

FIGS. 8A and 8B show cross sections corresponding to FIGS. 6A and 6B for the exemplary embodiment in accordance with FIG. 7A. The gate electrode layer is now patterned to form individual gate electrodes 34 on which residual portions of the hard mask layer 24 are present, over which run the strips of the patterned further hard mask layer 25. The openings between the ridges patterned in this way give a clear view, in the viewing direction, of the dielectric filling 42 arranged behind the plane of the cross section. Identical portions of the structures are again provided with the same reference symbols.

The differences between the exemplary embodiments described can be inferred from the comparison of FIGS. 6A and 8A, and 6B and 8B, respectively. In the case of the exemplary embodiment in accordance with FIG. 7B, a small difference results between the associated cross sections in accordance with FIGS. 8A and 8B in the height of the contour which delimits the top side of the further auxiliary layer 25; moreover, the hard mask layer 24 is obviated and replaced by lower portions of the further hard mask layer 25.

FIGS. 9A and 9B are cross sections in accordance with FIGS. 8A and 8B after further method steps involving application of further dielectric fillings 43 between the ridges, for which fillings a material is chosen with respect to which the material of the further hard mask layer 25 can be selectively etched. The top side is planarized. The further hard mask layer 25 is then completely removed. A material having a lower ohmic resistivity than that of highly doped silicon or highly doped germanium, preferably pure metal, is introduced into the resulting openings. A plurality of metal layers may be provided here. As an example, FIGS. 9A and 9B illustrate a thin first metal layer 47 and a second metal layer 48, which forms the main portion of the word lines. The first metal layer 47 may include, for example, titanium and a barrier layer made of TiN, while the second metal layer 48 is preferably tungsten. A further possibility, specified here only as an example, provides for forming the first metal layer from tantalum and a barrier layer made of TaN, while the second metal layer 48 is preferably copper. Other combinations of metals and metal nitrides are likewise possible here.

In each embodiment, the entire word line is formed only from layers having a low ohmic resistivity. Provision may also be made, and it is particularly preferred, for only a single homogeneous metal layer to be applied as word line. Both preferred fabrication methods illustrated result in the fabrication of semiconductor memory components whose word lines comprise pure metal with a sufficiently low percentage of impurities. Suitable lateral electrical insulations are provided in each case. The buried bit lines may, as necessary, be additionally provided with metallizations such as are described in German Patent Application 101 10 150 A1 cited in the introduction.

The invention makes it possible to fabricate the specified component structure with smaller period spacings (pitch) than has been possible heretofore. One advantage of this invention is, in particular, that the word lines can be formed with self-aligned contacts on the gate electrodes. The embodiment with a further hard mask layer 25 has the advantage, in particular, that all the high temperature steps, in particular the annealing of implants, can be carried out before the low-resistance material for the word lines is deposited and patterned. This primarily has the advantage that a material that only has to be able to withstand 450° C. can be chosen for the word line.

What is claimed is:

1. A method for fabricating semiconductor memory components, the method comprising:
forming a storage layer sequence over a semiconductor body;
forming gate electrodes adjacent the storage layer sequence, the gate electrodes comprising strip-type structures made of electrically conductive material;
forming source/drain regions by an implantation of dopant into the semiconductor body between the gate electrodes;
forming a dielectric filling between the gate electrodes;
forming word lines from at least one metal layer that makes electrical contact with the gate electrodes;
providing a dielectric material adjacent free sidewalls that encompass an upper region of the gate electrodes, the dielectric material forming word line spacers; and
forming a further dielectric filling into regions between mutually adjacent word lines and between mutually adjacent gate electrodes.

2. The method as claimed in claim 1, further comprising planarizing the dielectric layer before forming the at least one metal layer.

3. The method as claimed in claim 1, wherein the word line spacers are formed from a nitride of a semiconductor material of the semiconductor body.

4. The method as claimed in claim 3, wherein the word line spacers are formed from a silicon nitride.

5. The method as claimed in claim 1, wherein the at least one metal layer that makes electrical contact with the gate electrodes comprises pure tungsten.

6. The method as claimed in claim 1, wherein the at least one metal layer that makes electrical contact with the gate electrodes comprises pure molybdenum.

7. The method as claimed in claim 1, wherein forming gate electrodes comprises forming polysilicon gate electrodes.

8. The method as claimed in claim 1, wherein forming the storage layer sequence comprises a storage layer sequence from dielectric layers and a storage layer suitable for charge trapping is arranged therebetween.

9. The method as claimed in claim 8, wherein the dielectric layers comprise oxide layers and the storage layer comprises a nitride layer.

10. The method as claimed in claim 1, wherein the word lines are arranged transversely with respect to bit lines.

11. A method for fabricating semiconductor memory components, the method comprising:
forming a storage layer sequence over a semiconductor body;
forming gate electrode strips adjacent the storage layer sequence, the gate electrode strips comprising strip-type structures made of electrically conductive material;
forming source/drain regions by an implantation of dopant into the semiconductor body between the gate electrode strips;
forming a dielectric filling between the gate electrode strips;
forming a hard mask layer over the semiconductor body, the hard mask layer having openings between regions provided for word lines;
using the hard mask layer, removing portions of the gate electrode strips thereby forming individual gate electrodes;
forming a further dielectric filling in interspaces between portions of the dielectric filling, the individual gate electrodes and portions of the hard mask layer;
removing the hard mask layer; and
forming at least one metal layer that serves as a word line in regions previously occupied by the hard mask layer.

12. The method as claimed in claim 11, wherein forming gate electrode strips comprises:
forming a gate electrode layer over the storage layer sequence;
forming a first hard mask layer over the gate electrode layer;
using the first hard mask layer to pattern the gate electrode layer into the strip-type structures; and
removing the first hard mask layer before forming the hard mask layer that is used in removing portions of the gate electrode strips to form the individual gate electrodes.

13. The method as claimed in claim 11, wherein the at least one metal layer comprises titanium.

14. The method as claimed in claim 11, wherein the at least one metal layer comprises a TiN barrier layer and tungsten or tantalum.

15. The method as claimed in claim 11, wherein the at least one metal layer comprises a TaN barrier layer and copper.

16. The method as claimed in claim 11, wherein forming the gate electrode strips comprises forming polysilicon gate electrode strips such that the individual gate electrodes comprise polysilicon gate electrodes.

17. The method as claimed in claim 11, wherein forming the storage layer sequence comprises a storage layer sequence from dielectric layers and a storage layer suitable for charge trapping is arranged therebetween.

18. The method as claimed in claim 17, wherein the dielectric layers comprise oxide layers and the storage layer comprises a nitride layer.

19. The method as claimed in claim 11, wherein forming the at least one metal layer comprises forming at least one pure metal layer.

20. The method as claimed in claim 19, wherein forming the at least one metal layer consists of forming one or more pure metal layers.
